(19) United States
(12) Patent Application Publication
(10) Pub. No.: US 2005/0090925 A1
(43) Pub. Date: Apr. 28, 2005

(54) Method and device for control of the data flow on application of reticles in a semiconductor component production

(75) Inventors: Thomas Albrecht, Dresden (DE); Norbert Haase, Weixdorf (DE); Henning Haffner, Dresden (DE); Carmen Jahnert, Dresden (DE); Olaf Kronefeld, Dresden (DE); Manfred Stiegler, Dresden-Langedruch (DE)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Infineon Technologies AG, Munchen (DE)

(21) Appl. No.: 10/488,486

(22) PCT Filed: Aug. 28, 2002
(86) PCT No.: PCT/DE02/03196

(30) Foreign Application Priority Data
Aug. 30, 2001 (DE) 101 43 711.0

(51) Int. Cl. G03F 9/00; G06F 19/00

(52) U.S. Cl. 700/121; 700/115; 430/5

(57) ABSTRACT

A reticle control system and method in which each reticle is unambiguously assigned a structured reticle data set, and the content of each reticle data set is automatically changed and/or supplemented depending on use of the associated reticle in the semiconductor component production process for which the reticle was produced. The reticle data set is used to identify and control the reticles over the entire production sequence. The ability to change or supplement the reticle data sets facilitates progressively storing production-dictated information related to the use of the associated reticles, thereby enabling effective control of the reticles in the production process.

### BACKGROUND OF THE INVENTION

The invention relates to a method for control of the data flow on application of reticles in a semiconductor component production process and a device for carrying out this method.

During the production of semiconductor components, numerous complex structures are applied to a semiconductor material. Exposure methods are used for this purpose, during which the complex structures are applied to the semiconductor material by means of reticles. The number of reticles required for the exposure increases greatly as the complexity increases. In this case, for each step of the production process, the correct reticle must be at the correct location.

At the present time, the required reticles are ordered by means of a separate written instruction at a design center. The instruction contains information about the layout of the semiconductor component to be produced and the kerf region.

On the basis of these data, the reticles are produced as chromium structures on a quartz glass carrier. In this case, control marks, structure widths and distances are also measured at predefined measurement locations on the reticle. These measurement data are used to create a measurement record which is conveyed together with the reticle to the customer.

In practice, there is a great diversity of measurement record standards, so that this information cannot directly be processed further in the production of the semiconductor components without complicated processing. For this reason, the programs for the test installations (CD and overlay measuring apparatuses) have to be created partly automatically or even manually. In addition to an increased outlay, this procedure is also susceptible to errors. Moreover, it is not possible at the present time to manage and use the reticle stock of a production line efficiently, since central information, e.g. about the state of the reticles or the versions of a reticle used, is lacking. Therefore, it is also not possible to initiate an efficient preventive inspection of the reticles in the production process.

Even if the production of the semiconductor components themselves is automated, the handling of a large number of reticles still poses a problem. Although a multiplicity of operating data acquisition systems are known (WO 01/37121 A2 shall be mentioned as one example among many), they cannot efficiently solve the specific problems in reticle handling in the production of semiconductor components.

### SUMMARY OF THE INVENTION

The present invention is directed to a method and a device that addresses the problems mentioned above, and with which the use of reticles in a semiconductor component production can be efficiently controlled.

The production control of the reticles is improved according to the invention by virtue of the fact that the reticles are in each case unambiguously assigned a structured reticle data set, the content of the reticle data set being automatically changed and/or supplemented depending on the production process for a semiconductor component. The unambiguous assignment of the reticle data set to a respective reticle ensures that the latter can be unambiguously identified and thus controlled over the entire production sequence. The possibility of changing or supplementing the structured data set means that production-dictated information can be progressively stored and made available. This enables effective control of the reticles in the production process.

In this case, it is particularly advantageous if the reticle data sets are stored and processed in a central data processing system. The central control entity makes it possible to process the application of the reticles in connection with other production information.

The method has a particularly advantageous effect if the reticle data sets have production information of the reticles, in particular about a chip layout and about kerf data. This enables reticles to be ordered efficiently and without errors, the order data in particular also remaining available for reorders.

Furthermore, it is advantageous if the reticle data sets have information about measurement locations on the reticles and/or data about test measurements at the reticles. This information is usually generated during the production of the reticles, but is not used until later in the production. It is precisely here that the advantage of the structured reticle data set is manifested, which can be used in different phases of the production. The electronic provision of measurement location descriptions (kerf data) enables an automatic generation of measurement sequences for the control and measurement installations of the wafer production. As a result, it is possible to react more rapidly to alterations in the wafer processing process. At the same time, input errors are avoided.

In a further advantageous embodiment of the method according to the invention, the reticle data sets have information about at least one measurement record of the reticles. This measurement record, too, is required later in the production and is made available there by the reticle data set.

This is particularly advantageous if at least one control program for test devices of the reticles is created automatically by the central data processing system on the basis of the reticle data sets. Time-consuming and error-susceptible manual creations of the control programs are thus obviated.

It is also advantageous if changed programs for measuring and test devices for the reticles are automatically generated by the central database system in the event of production-dictated changes of specifications and/or tolerance limits of the reticles. Precisely this is an essential advantage of the central information management by means of a reticle data set.

For process control purposes, it is advantageous if a reticle data set has information about the identity of the reticle, a release number, the instantaneous location of the reticle, the instantaneous use of the reticle, the state, the application duration of the reticle and/or the production history of the reticle.

Moreover, in an advantageous refinement of the method according to the invention, the central data processing system controls the application of the reticles in the production in a manner dependent on the information of the reticle data sets. In particular, assignments of specific reticles to installations during the production of the semiconductor components are created. Thus, the correct reticles are made available at the exposure installations when they are required.

Furthermore, it is advantageous if the central data processing system, on the basis of the information of the reticle data sets, in particular of the application frequency of the reticles, feeds the reticles automatically to a preventive inspection and/or cleaning and initiates a storage in a storage container and/or a reorder of reticles. Bottlenecks or production stoppages are thereby avoided.

The automatic exchange and/or the automatic processing of the reticle data set between a reticle manufacturer and a semiconductor component manufacturer, in particular in the context of a virtual fabrication cluster, reduces the error possibilities and facilitates the production planning.

In the case of the exchange of the reticle data sets, it is advantageous if the reticle data sets are exchanged via the Internet. The processing of the reticle data sets by means of an HTML input mask is particularly advantageous, since it is simple to implement.

It is also advantageous if the central database system automatically creates tags for reticles and/or containers for reticles in a manner dependent on the reticle data set. Reticles can be handled individually, in so-called single pods or in multiple pods, pods generally being provided with a tag (marking). Said tag may be provided with reticle information (e.g. bar code of the reticles contained in the pod) or with an identification number. This information can be used to control the reticle logistics within the production if reticle pods are used. The movement of these pods is tracked by the central data processing system and is also used from here for pod control (manual or automatic movement of pods to specific installations).

The object is also achieved by means of a device for carrying out the method according to the invention.

### BRIEF DESCRIPTION OF THE FIGURE

The invention is explained in more detail below using an exemplary embodiment with reference to the figure of the drawing, in which:

FIG. 1 shows a schematic illustration of the data flows of an embodiment of the method according to the invention.

### DETAILED DESCRIPTION OF THE FIGURE

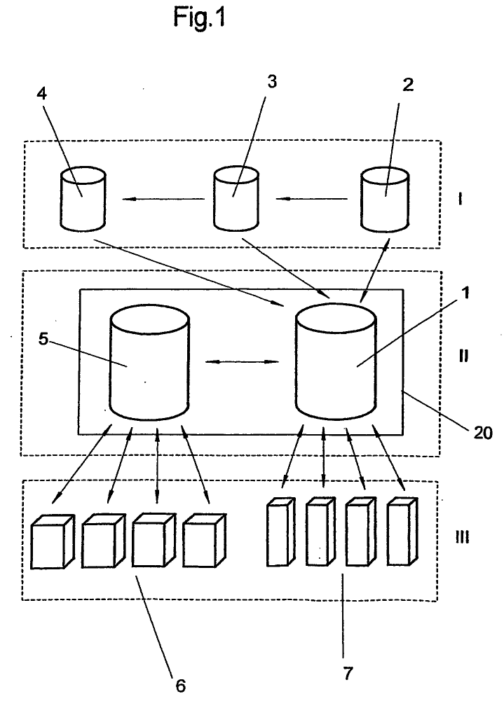

FIG. 1 illustrates three planes I, II, III which play a part in the production of semiconductor components in conjunction with the method according to the invention.

The first plane I relates to the production of the reticles (not illustrated here) themselves. The second plane II relates to databases 1, 5, which are part of the central data processing system 20 for the control of the method. The third plane III relates to the control of the application of the reticles in the production of the semiconductor components.

The arrows between the units of the three planes I, II, III and between the three planes I, II, III symbolize the data flow.

The reticle order data including the specification limits are input by the customer into the reticle database 1 of the central data processing system 20, stored there and transmitted via the Internet or some other data line to an order database 2 of a reticle manufacturer. A particularly convenient processing of such orders can be achieved by means of Web portals.

The information which is transmitted in this case about the layout of the reticle, including the kerf data, form the first part of a structured reticle data set, which is logically unambiguously coupled to a reticle. In this case, a reticle data set is also understood to mean a combination of different files which may be arranged on different computers. Said files are, however, logically all assigned to a reticle data set which is logically coupled to the reticle. Such a structure which is stored in distributed fashion but is logically contiguous can also have the effect that the information relating to the reticle is centrally accessible and evaluatable.

Said reticle data set is stored in the reticle database 1 and kept up to date, parts of the reticle data set being made available in each case to other units, such as e.g. the production. Conversely, each unit involved in the production of the semiconductor components can access the reticle data set of the reticles in order e.g. to find specific reticles.

The reticle order data are transmitted from the order database 2 to a kerf database 3, the order data also being combined with manufacturer data of the reticle manufacturer. The kerf data are stored in a kerf database 3 and the central reticle database 1. The structured reticle data set is automatically supplemented with the corresponding new data.

After the production of the reticle, this is subjected to extensive measurement and test programs. The results (quality result sheets) obtained in this case are stored in a test database 4 and are also transmitted to the reticle database 1, where the reticle data set of the relevant reticle is once again supplemented. The further use of these records is described further below.

During the entire process of reticle production, at certain intervals, e.g. at the beginning of a new production step, information is automatically sent to the reticle database in order to be able to establish the progress of each reticle in the production process.

If the reticle is supplied to the production installations 6, then this information is also transmitted to the reticle database 1. The reticle database 1 is connected as part of the central data processing system 20, to a production database 5. The production database 5 controls, inter alia, application of the reticles in the production installations 6, i.e. when, where, which reticle is employed.

All of the reticles which are not required in the production installations 6 at a given point in time are in this case arranged in a reticle store 7. The central reticle database 1, which, on account of the stored reticle data sets, has an overview of the application of the reticles, has the data management of said reticle store 7.

The application of the reticles in the production installations 6 is controlled by the production database 5. The latter also accesses the reticle data sets which are assigned to the reticles.

The production database 5 defines when and where which reticle is employed. For this purpose, there is a connection to all the exposure units of the production line. The production database also automatically establishes how long a reticle has been employed. This information is likewise part of the reticle data set which is assigned to each reticle.

By establishing the application durations of the reticles, maintenance, cleaning and inspection times can be defined automatically. The preventive inspections can be controlled automatically on the basis of the data about the application durations which are stored in the production database 5. In this case, the production database 5 controls the sequence such that a replacement is ready for the reticle to be tested, in order not to disturb the production process.

The central reticle database 1 also has a logistics database, which controls the reorder of reticles. Thus, on the basis of the reticle data set of a reticle, the database can infer when the planned service life of a reticle will have elapsed and automatically perform a replacement order in good time beforehand. This is done by means of the order database 2. The necessary data for the reorder can be taken from the reticle data set. Moreover, an increased number of reticles may be ordered by means of the logistics database if this is required by changes in the production sequence.

The reticle data set contains information about measurement and test operations during the production of the reticle. Since these records are present in a machine-readable, uniform format, these data can be used in the production to automatically program the corresponding test installations. The test installations thus receive, relative to a reticle, e.g. information about the layout, measurement locations, etc., so that the test operations can be implemented efficiently.

Data about test measurements (quality result) in the reticle data set (e.g. measurement records) are important if, in the case of ever shrinking structures and structural dimensions, not all the specifications can be met by the reticle manufacturer, since there are technical limits here as well. In this case, the production has to accept such deviations in the specification of a reticle, if appropriate even with dynamic regulating parameters (in the case of lithographic structure transfer for example by means of exposure parameters such as dose, numerical aperture or annular diaphragm or zone-dependent focus). Such regulating mechanisms can only be controlled electronically with a reticle data set as described here.

Should test routines have changed, then the changes can be defined centrally and implemented automatically in a decentralized manner in the production.

A further aspect of the use of a reticle data set according to the invention resides in comprehensive application of the reticles given the existence of different installations in a semiconductor production. If possible, the reticles are intended to be employed if possible on any machine present.

This is not actually attained, however, since, with quasi-static regulating limits, the respective production tolerances (CD (critical dimension), overlay) are not achieved by every installation.

The handling system with a reticle data set as described here enables, in conjunction with a database system 20 containing batch-related production data concerning critical dimension and overlay, a dynamic regulation of the production process. Given structure widths and spacings which lie in the vicinity of the structure transfer limit with inclusion of the phase (phase mask), an efficient production thus actually becomes possible for the first time.

A further aspect is a reliable production process. Reticles can be released or blocked for the production at a central location. If a reticle is marked as blocked for the production in the database, wafer exposures are prevented online without a time delay with this reticle. Rework or scrap is thereby avoided.

The described functions of the method according to the invention yield the features of the device according to the invention, which has, in particular, a central data processing system.

The embodiment of the invention is not restricted to the preferred exemplary embodiments specified above. Rather, a number of variants are conceivable which make use of the method according to the invention and the device according to the invention also in the case of embodiments of a fundamentally different configuration.

List of Reference Symbols

1 Central reticle database
2 Order database
3 Kerf database
4 Test database
5 Production database
6 Production installations
7 Reticle store
20 Central data processing system

1. A method for control of the data flow on application of reticles in a semiconductor component production process, the method comprising:
unambiguously assigning each reticle an associated structured reticle data set; and
automatically changing/supplementing the content of the reticle data set for each reticle in response to use of said each reticle in the semiconductor component production process,
wherein automatically changing/supplementing the reticle data set comprises assigning each reticle to at least one of a production installation during the semiconductor component production process and a maintenance installation according to assignment data prescribed in the associated changed/supplemented reticle data set.

2. The method as claimed in claim 1, wherein automatically changing/supplementing the reticle data set further comprises automatically initiating a reorder of the reticles on the basis of reorder information of the reticle data sets.

3. The method as claimed in claim 1, further comprising assigning to each the reticle data set production information of the associated reticle, in particular about a chip layout and about kerf data associated with the reticle.

4. The method as claimed in claim 1, further comprising storing and processing the reticle data sets in a central data processing system.

5. The method as claimed in at claim 1, further comprising assigning to each the reticle data set information about at least one of measurement locations on the associated reticle and data about test measurements at the associated reticle.

6. The method as claimed in claim 1, further comprising assigning to each reticle data set information about at least one measurement record of the associated reticle.

7. The method as claimed in claim 4, further comprising automatically creating at least one control program for test devices of each reticle by the central data processing system on the basis of the associated reticle data set.

8. The method as claimed in claim 7, further comprising automatically generating changed programs for measuring and test devices for each reticle by the central database system in the event of production-dictated changes of at least one of specifications and tolerance limits of said each reticle.

9. The method as claimed in claim 1, wherein assigning and automatically changing/supplementing each reticle data set for each associated reticle includes assigning and updating at least one of a release number, an instantaneous location of the associated reticle, the instantaneous use of the reticle, the state, the application duration of the reticle and the production history of the reticle.

10. The method as claimed in claim 4, further comprising utilizing the central data processing system, on the basis of the information of the reticle data sets, to automatically feed the reticles to at least one of a preventive inspection unit, a cleaning unit, and a storage container.

11. The method as claimed in claim 1, further comprising the reticle data set is automatically exchanged, and/or processed, between a reticle manufacturer and a semiconductor component manufacturer in particular in the context of a virtual fabrication cluster.

12. The method as claimed in claim 1, further comprising transmitting the reticle data sets via the Internet.

13. The method as claimed in claim 1, further comprising processing the reticle data sets by means of an HTML input mask.

14. The method as claimed in claim 4, further comprising utilizing the the central database system to automatically create tags for one of the reticles and containers for storing the reticles in a manner dependent on the reticle data set.

15. A method for control of the data flow on application of reticles in a semiconductor component production process, the method comprising:
unambiguously assigning each reticle an associated structured reticle data set; and
automatically changing/supplementing the content of the reticle data set for each reticle in response to use of said each reticle in the semiconductor component production process,
wherein automatically changing/supplementing the reticle data set comprises automatically initiating a reorder of the reticles on the basis of reorder information of the reticle data sets.

16. A device for controlling the data flow on application of reticles in a semiconductor component production process, the device comprising:
means for unambiguously assigning each reticle an associated structured reticle data set; and
means for automatically changing/supplementing the content of the reticle data set for each reticle in response to use of said each reticle in the semiconductor component production process,
wherein automatically changing/supplementing the reticle data set comprises assigning each reticle to at least one of a production installation during the semiconductor component production process and a maintenance installation according to assignment data prescribed in the associated changed/supplemented reticle data set.
